(19) United States
(12) Patent Application Publication
(10) Pub. No.: US 2026/0361048 A1
(43) Pub. Date: Nov. 12, 2026

(54) LIGHT-EMITTING DEVICE

(71) Applicant: NICHIA CORPORATION, Anan-shi, Tokushima (JP)

(72) Inventor: Masahiro NISHIOKA, Myozai-gun, Tokushima (JP)

(21) Appl. No.: 19/121,749

(22) PCT Filed: Oct. 19, 2023
(86) PCT No.: PCT/JP2023/037794

§ 371 Date: Apr. 16, 2025

(30) Foreign Application Priority Data
Oct. 20, 2022 (JP) 2022-168717

(51) Int. Cl. H01S 5/023; H01S 5/0234; H01S 5/40

(52) U.S. Cl. CPC H01S 5/023; H01S 5/0234; H01S 5/4087

(57) ABSTRACT

A light-emitting device that emits light with a good polarization ratio is provided. The light-emitting device includes: a first submount including a ceramic substrate containing AlN, and a plurality of upper metal layers disposed on an upper surface side of the ceramic substrate; and a first semiconductor laser element disposed on an upper surface of the first submount, and configured to oscillate in a TM mode. The plurality of upper metal layers include one or more upper first metal layers comprising a metal layer containing at least Ni.

### TECHNICAL FIELD

The present invention relates to a light-emitting device.

### BACKGROUND ART

Patent Literature 1 discloses a submount in which a main conductor layer made of Au, Ag, Cu, or Al is formed on an insulating base body made of sintered aluminum nitride, sintered silicon carbide, diamond, silicon, sintered aluminum oxide, a sintered glass ceramic, sintered silicon nitride, quartz, sapphire, or a cubic boron nitride ceramic, a barrier layer made of Pt, Pd, Rh, Ru, Ni, a Ni—Cr alloy, or a Ti—W alloy is formed on this, an Au—Sn alloy layer is formed on this, and a Ni layer is further formed on this. Patent Literature 1 also indicates that a submount such as this can reduce the possibility of misalignment of an optical semiconductor element.

### CITATION LIST

### Patent Literature

Patent Literature 1: Japanese Unexamined Patent Application Publication No. 2008-34581

### SUMMARY OF INVENTION

### Technical Problem

In a light-emitting device including a semiconductor laser element, it is sometimes necessary for the polarization ratio of light (laser light) emitted from the light-emitting device to be equal to or higher than a predetermined value. In the case where a semiconductor laser element is disposed on a submount in a light-emitting device, the polarization ratio of the light emitted from the semiconductor laser element can be affected by the materials that are used and configuration of the submount.

### Solution to Problem

A light-emitting device disclosed in the embodiments includes a first submount including a ceramic substrate containing AlN, and a plurality of upper metal layers disposed on an upper surface side of the ceramic substrate; and a first semiconductor laser element disposed on an upper surface of the first submount, and configured to oscillate in a TM mode. The plurality of upper metal layers include one or more upper first metal layers comprising a metal layer containing at least Ni.

A light-emitting device that emits light with a good polarization ratio is realized in at least one of the one or more inventions disclosed in the embodiments. Alternatively, a light-emitting device that emits red light with a polarization ratio value of 100 or more is realized in at least one of the one or more inventions disclosed in the embodiments.

### BRIEF DESCRIPTION OF DRAWINGS

FIG. 1 is an oblique view of a light-emitting device according to an embodiment.

FIG. 2 is a top view of the light-emitting device according to the embodiment.

FIG. 3 is an oblique view showing the state before the optical members of the light-emitting device according to the embodiment are mounted.

FIG. 4 is a top view in the state of FIG. 3.

FIG. 5 is an oblique view of the constituent elements disposed inside the light-emitting device according to an embodiment.

FIG. 6 is a top view in the state shown in FIG. 5.

FIG. 7 is a top view of the state shown in FIG. 6 when the conducting member has been removed.

FIG. 8 is a cross-sectional view along the VIII-VIII line in FIG. 7.

FIG. 9 is a cross-sectional view along the IX-IX line in FIG. 7.

FIG. 10A is a cross-sectional view of a submount according to an embodiment.

FIG. 10B is a cross-sectional view of a submount having a structure different from that of the submount according to the embodiment.

FIG. 10C is a cross-sectional view of a state in which a semiconductor laser element is disposed on the submount according to the embodiment.

FIG. 10D is a cross-sectional view of a state in which a semiconductor laser element is disposed on the submount according to the embodiment.

FIG. 11 is a schematic diagram of the experimental environment in an experiment for measuring the polarization ratio, conducted in a state in which a semiconductor laser element is disposed on the submount.

### DESCRIPTION OF EMBODIMENTS

In this description or the claims, polygons such as triangles and quadrangles, including shapes in which the corners of the polygon are rounded, chamfered, beveled, coved, or the like, are referred to as polygons. Furthermore, not only shapes with modification at their corners (ends of sides), but also shapes with modification at intermediate portions of sides thereof are similarly referred to as a polygon. That is, a polygon-based shape with partial modification is included in the interpretation of “polygon” described in this specification and the claims.

The same applies not only to polygons but also to terms representing specific shapes such as trapezoids, circles, protrusions, and recesses. Furthermore, the same applies when dealing with each side forming that shape. That is, even if a corner or an intermediate portion of a certain side is modified, the interpretation of “side” includes the modified portion. When a “polygon” or “side” not partially processed is to be distinguished from a processed shape, “strict” will be added to the description as in, for example, “strict quadrangle”.

Further, in the description and the claims, descriptions such as upper and lower (upward/downward), left and right, top and bottom, front and back (forward/backward), and near and far are used merely to describe the relative relationship of positions, orientations, directions, and the like, and the expressions need not necessarily match an actual relationship at the time of use.

In the drawings, directions such as an X direction, a Y direction, and a Z direction may be indicated by using arrows. The directions of the arrows are the same across multiple drawings of the same embodiment. In the drawings, a direction of the arrow in which X, Y, and Z are indicated is referred to as a positive direction, and a direction opposite to the positive direction is referred to as a negative direction. For example, the direction in which X is pointed by the arrow is the X direction and the positive direction. Note that a direction being the X direction and the positive direction is referred to as a “positive X direction,” and a direction opposite to the positive X direction is referred to as a “negative X direction.” The same applies to the Y direction and the Z direction.

Further, “member” and “portion” may be described when, for example, a component and the like are described in this description. The term “member” refers to an object treated as physically single component. The object treated as physically single component can be an object treated as one part in a manufacturing step. On the other hand, the term “portion” refers to an object that may not be treated as physically single component. For example, the term “portion” is used when a part of one member is partially regarded.

Note that the distinction between “member” and “portion” described above does not indicate an intention to consciously limit the scope of rights in interpretation of the doctrine of equivalents. In other words, even when there is a component described as “member” in the claims, this does not mean that the applicant recognizes that treating the component as physically single component is essential for application of the present invention.

Furthermore, in the description and the claims, when there are a plurality of components and each of these components is to be indicated separately, the components may be distinguished by adding the terms “first” and “second” before the name of the component. Further, objects to be distinguished may differ between the description and the claims. Thus, even when a component in the claims is given the same term as that in the description, the object indicated by that component is sometimes not be the same across the description and the claims.

For example, when there are components distinguished by being termed “first”, “second”, and “third” in the description and the components given the terms “first” and “third” in the description are described in the claims, these components may be distinguished by being denoted as “first” and “second” in the claims for ease of understanding. In this case, the components denoted as “first” and “second” in the claims refer to the components termed “first” and “third” in the description, respectively. This rule is not limited to components but also applies to other objects in a reasonable and flexible manner.

Embodiments for implementing the present invention will be described below. Furthermore, specific embodiments for implementing the present invention will be described below with reference to the drawings. Embodiments for implementing the present invention are not limited to the specific embodiments. In other words, the illustrated embodiments are not the only form in which the present invention is realized. Sizes, positional relationships, and the like of members illustrated in the drawings may sometimes be exaggerated in order to facilitate understanding.

### EMBODIMENT

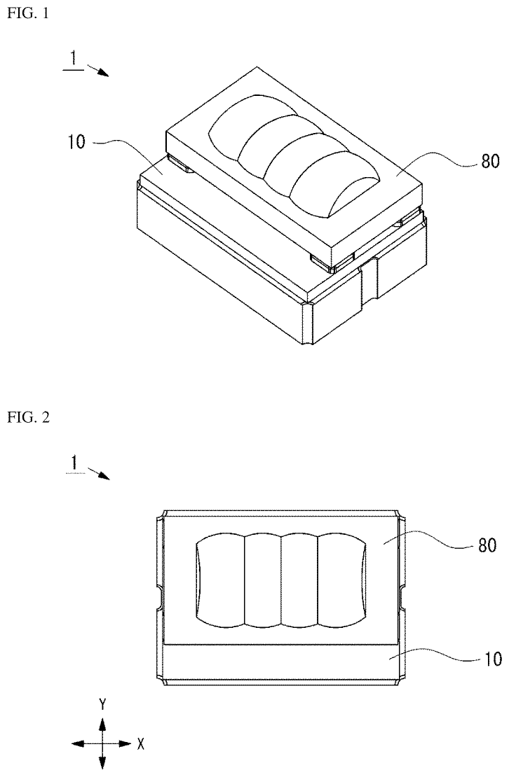

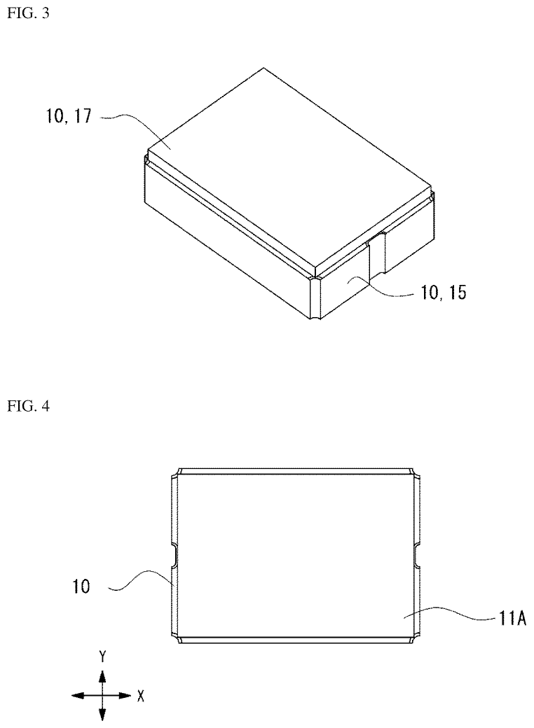

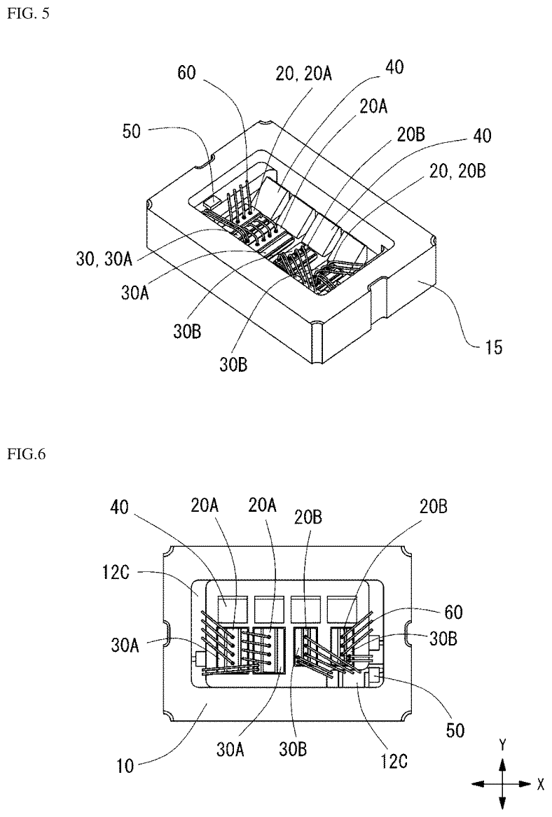

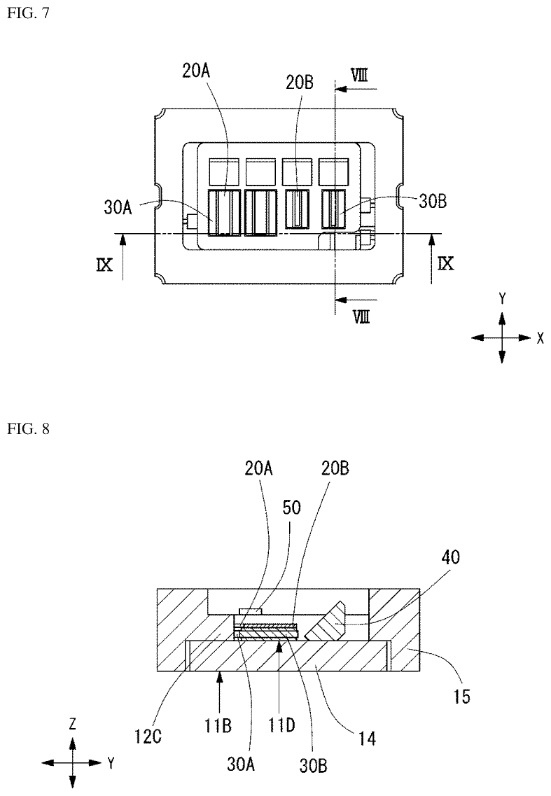

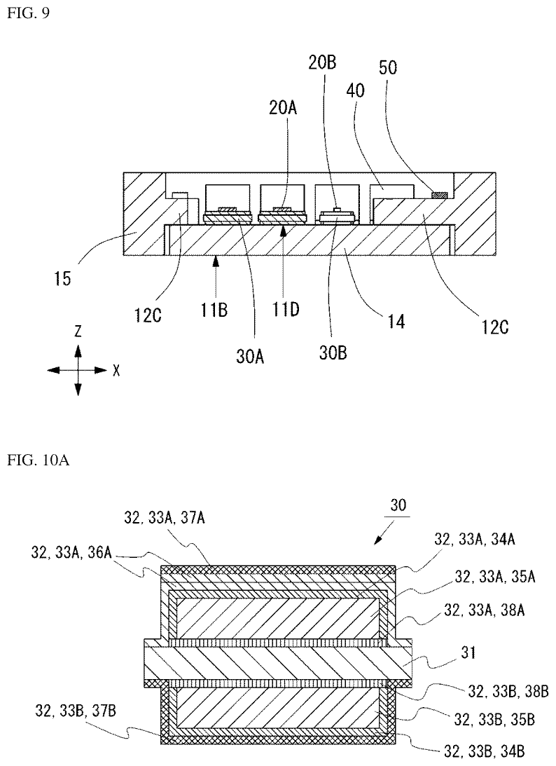

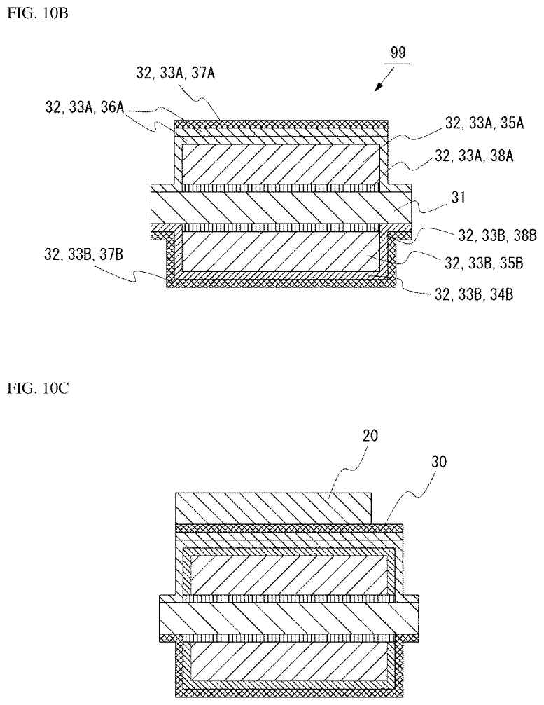

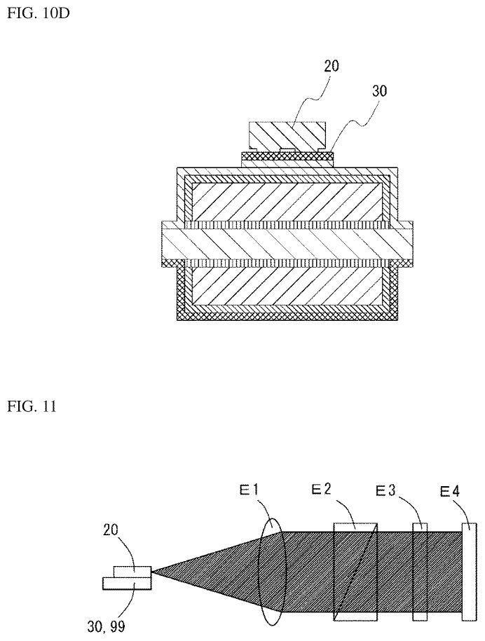

A light-emitting device 1 according to an embodiment will now be described. FIGS. 1 to 9 are diagrams illustrating an example of an embodiment of the light-emitting device 1. FIG. 1 is an oblique view of the light-emitting device 1. FIG. 2 is a top view of the light-emitting device 1. FIG. 3 is an oblique view showing a state before an optical member 80 of the light-emitting device 1 is mounted. FIG. 4 is a top view in the state of FIG. 3. FIG. 5 is an oblique view illustrating the constituent elements disposed inside the light-emitting device 1. FIG. 6 is a top view in the state of FIG. 5. FIG. 7 is a top view of a state in which the conducting member 60 has been removed from the state shown in FIG. 6. FIG. 8 is a cross-sectional view along the VIII-VIII line in FIG. 7. FIG. 9 is a cross-sectional view along the IX-IX line in FIG. 7. FIG. 10A is a schematic cross-sectional view of a submount 30. FIG. 10B is a schematic cross-sectional view of a submount 99. FIGS. 10C and 10D are schematic cross-sectional views of a state in which a semiconductor laser element 20 is disposed on the submount 30.

The light-emitting device 1 includes a plurality of constituent elements. These constituent elements include a package 10, one or more semiconductor laser elements 20, one or more submounts 30, one or more reflective members 40, one or more protective elements 50, a plurality of conducting members 60, and an optical member 80.

The light-emitting device 1 may include other constituent elements. For example, the light-emitting device 1 may include a light-emitting element such as a light-emitting diode or a semiconductor laser element in addition to the one or more semiconductor laser elements 20. Also, the light-emitting device 1 need not include some of the constituent elements described here.

First, each constituent element will be described.

### Package 10

The package 10 includes a base portion 14, a frame portion 15, and a covering portion 17. The package 10 includes, for example, a base member that constitutes the base portion 14 and the frame portion 15, and a cover that constitutes the covering portion 17. The base member may be formed by bonding a mounting member that constitutes the base portion 14 and a frame member that constitutes the frame portion 15. Alternatively, the package 10 may include a base member that constitutes the base portion 14, and a cover that constitutes the frame portion 15 and the covering portion 17.

The package 10 has a mounting surface 11D on which other constituent elements are disposed. A closed space is formed inside the package 10. The mounting surface 11D is provided in the interior of this closed space. This internal space (the closed space formed in the interior) is a sealed space. Also, this internal space is a space that is sealed in an airtight state with a specific atmosphere contained therein.

The package 10 has a top surface 11A, a bottom surface 11B, and a mounting surface 11D. The base portion 14 has the mounting surface 11D. Also, the covering portion 17 has the top surface 11A, and the base portion 14 has the bottom surface 11B. The frame portion 15 surrounds the mounting surface 11D in top view. The outer edge shape of the package 10 is rectangular in a top view. However, the outer edge shape of the package 10 does not have to be rectangular.

The base member has one or more step portions 12C. Each step portion 12C has an upper surface and an inner lateral surface that intersects the upper surface and extends downward from the upper surface. The upper surface of each step portion 12C is located above the mounting surface 11D.

One or more wiring patterns are provided at the upper surface of the step portion 12C. The wiring patterns are electrically connected to other wiring patterns of the frame portion 15 via the conducting member passing through the inside of the frame portion 15. For example, the wiring pattern provided at the upper surface of the step portion 12C is electrically connected to the wiring pattern provided at the lower surface of the frame portion 15.

The main material of the mounting member is a metal or a composite containing a metal, for example. An example of the main material of the mounting member is copper. Also, for example, the main material of the frame member is a ceramic. Examples of the ceramic that serves as the main material of the frame member include aluminum nitride, silicon nitride, and aluminum oxide. The main material of the cover is, for example, quartz, silicon carbide, sapphire, or glass. The main material of the mounting member may be a ceramic. For example, in the case where the base portion 14 and the frame portion 15 are integrally formed from the same material, the main material of the base member may be a ceramic.

As used herein, the “main material” refers to the material that accounts for the largest percentage by weight or volume in the target structure. In the case where the target structure is formed from one material, that material is the main material. In other words, the expression that a given material is the main material encompasses a case in which the proportion of that material is 100%.

### Semiconductor Laser Element 20

The semiconductor laser element 20 has a light-emitting surface from which light is emitted. The semiconductor laser element 20 has an upper surface, a lower surface, and a plurality of lateral surfaces. The lateral surfaces of the semiconductor laser element 20 serve as light-emitting surfaces. The upper surface of the semiconductor laser element 20 has a rectangular shape having long sides and short sides. However, the shape of the upper surface of the semiconductor laser element 20 does not have to be rectangular.

A semiconductor laser element having a single emitter can be used as the semiconductor laser element 20. Alternatively, a multi-emitter semiconductor laser element, which has a plurality of emitters, can be used as the semiconductor laser element 20. For example, a semiconductor laser element having two emitters can be used as the semiconductor laser element 20.

A semiconductor laser element that emits red light can be used as the semiconductor laser element 20, for example. Alternatively, a semiconductor laser element that emits green light can be used as the semiconductor laser element 20. Alternatively, a semiconductor laser element that emits blue light can be used as the semiconductor laser element 20. It is also possible to use a semiconductor laser element that emits light of other color as the semiconductor laser element 20.

As used herein, “blue light” refers to light whose emission peak wavelength is in the range of 420 to 494 nm, “green light” refers to light whose emission peak wavelength is in the range of 495 to 570 nm, and “red light” refers to light whose emission peak wavelength is in the range of 605 to 750 nm.

The light (laser light) emitted from the semiconductor laser element 20 has divergence. Also, the light emitted from the emission end surface (light emission surface) of the semiconductor laser element 20 is divergent light.

The light emitted from the semiconductor laser element 20 forms an elliptical far-field pattern (hereinafter referred to as “FFP”) in a plane parallel to the light emission end surface. “FFP” refers to the shape and intensity distribution of the emitted light at a position away from the emission end surface.

The light passing through the center of the elliptical shape of the FFP, or in other words, the light with the peak intensity in the light intensity distribution of the FFP, will be hereinafter referred to as the “light traveling along the optical axis”, or the “light passing through the optical axis”. Also, in the light intensity distribution of the FFP, the light having an intensity of at least 1/e² with respect to the peak intensity value will be referred to as the main portion of the light.

The shape of the FFP of the light emitted from the semiconductor laser element 20 is an ellipse in which the stacking direction is longer than the direction perpendicular to the stacking direction in a plane parallel to the light emission end surface. The “stacking direction” is the direction in which a plurality of semiconductor layers including the active layer are stacked in the semiconductor laser element 20. The direction perpendicular to the stacking direction can also be referred to as the in-plane direction of the semiconductor layers. The long axis direction of the elliptical shape of the FFP can also be referred to as the fast axis direction of the semiconductor laser element 20, and the short axis direction can also be referred to as the slow axis direction of the semiconductor laser element 20.

The angle of divergence of light of 1/e² of the peak light intensity based on the light intensity distribution of the FFP will be referred to as the angle of divergence of light of the semiconductor laser element 20. Other than as the light intensity of 1/e² of the peak light intensity, the angle of divergence of light can also be determined as the light intensity of one-half of the peak light intensity. In the description of this specification, the term “angle of divergence of light” as used alone refers to the angle of divergence of light at the light intensity of 1/e² of the peak light intensity. The angle of divergence in the fast axis direction is greater than the angle of divergence in the slow axis direction.

The semiconductor laser element 20 can be a semiconductor laser element that includes an active layer made of a GaAs-based material. The semiconductor laser element 20 can also be a semiconductor laser element that includes an active layer made of a GaN-based material.

For instance, an example of the semiconductor laser element 20 that emits blue light or the semiconductor laser element 20 that emits green light is a semiconductor laser element that includes an active layer made of a GaN-based material. Examples of this GaN-based material include GaN, InGaN, and AlGaN. An example of the semiconductor laser element 20 that emits red light is a semiconductor laser element that includes an active layer made of a GaP-based or GaAs-based semiconductor material. Examples of this GaAs-based material include GaAs and AlGaAs.

Examples of the GaP-based material include GaP, AlGaP, and AlGaInP. The active layer may be constituted by a semiconductor containing As and P, such as GaAsP.

### Submount 30

The submount 30 has an upper surface and a lower surface. The thickness of the submount 30 is 170 μm or greater and 500 μm or less. The submount 30 has a ceramic substrate 31 and a plurality of metal layers 32. The ceramic substrate 31 has an upper surface and a lower surface. The plurality of metal layers 32 include a plurality of upper metal layers 33A provided on the upper surface side of the submount 30. The plurality of metal layers 32 may also include a plurality of lower metal layers 33B provided on the lower surface side of the submount 30. The plurality of metal layers 32 may constitute the upper surface and the lower surface of the submount 30.

The ceramic substrate 31 contains aluminum nitride (AlN). The main material of the ceramic substrate 31 is aluminum nitride. Among ceramic materials, aluminum nitride is regarded as a material with relatively good heat dissipation properties. By using this material, a submount 30 with good heat dissipation properties can be obtained. The thickness of the ceramic substrate 31 is equal to or greater than 150 μm and equal to or less than 300 μm.

The upper metal layers 33A include one or more upper first metal layers 34A having a metal layer containing at least Ni. Furthermore, the one or more upper first metal layers 34A may include a metal layer containing Au.

The thickness of the metal layer containing Ni among the one or more upper first metal layers 34A is equal to or greater than 1 μm and equal to or less than 5 μm. The thickness of the one or more upper first metal layers 34A is equal to or greater than 1.01 μm and equal to or less than 5.1 μm. The thickness of the metal layer 32 refers to the thickness in the direction perpendicular to the surface with which the metal layer 32 is in contact.

The upper metal layers 33A include an upper second metal layer 35A provided between the ceramic substrate 31 and the one or more upper first metal layers 34A. The upper second metal layer 35A is a metal layer containing Cu. The main material of the upper second metal layer 35A is Cu. A metal other than Cu that has good heat dissipation properties may be used for the upper second metal layer 35A.

The thickness of the upper second metal layer 35A is greater than the thickness of the one or more upper first metal layers 34A. The thickness of the upper second metal layer 35A is equal to or greater than 10 μm and equal to or less than 100 μm. The upper second metal layer 35A is the thickest of the upper metal layers 33A.

The upper metal layers 33A, on the upper surface side of the ceramic substrate 31, include one or more upper third metal layers 36A including a metal layer 32 containing at least Pt provided on the upper surface side of the one or more upper first metal layers 34A.

The one or more upper third metal layers 36A may further include a metal layer containing TI. The one or more upper third metal layers 36A may further include a metal layer containing Au. The one or more upper third metal layers 36A include two metal layers containing Pt, between which a metal layer containing a metal other than Pt is disposed. The thickness of the one or more upper third metal layers 36A is equal to or greater than 0.5 μm and equal to or less than 1.5 μm.

The upper metal layers 33A include a top metal layer 37A that is provided at the highest position among the upper metal layers 33A. The top metal layer 37A is a metal layer containing Au, or a metal layer containing an AuSn alloy. The thickness of the top metal layer 37A is equal to or greater than 0.01 μm and equal to or less than 5 μm. The top metal layer 37A may constitute the upper surface of the submount 30.

In relation to the top metal layer 37A, the one or more upper first metal layers 34A can be considered to be intermediate metal layers provided between the ceramic substrate 31 and the top metal layer 37A. Similarly, in relation to the top metal layer 37A, the upper second metal layer 35A and the upper third metal layer 36A can be considered as intermediate metal layers provided between the ceramic substrate 31 and the top metal layer 37A.

The upper metal layers 33A include a bottom metal layer 38A that is disposed at the lowest position among the upper metal layers 33A. The bottom metal layer 38A can be a metal layer containing TiW, a metal layer containing Cu, or a metal layer containing Ni. The thickness of the bottom metal layer 38A is equal to or greater than 0.05 μm and equal to or less than 0.15 μm.

The lower metal layers 33B include one or more lower first metal layers 34B including a metal layer containing at least Ni. Furthermore, the one or more lower first metal layers 34B may include a metal layer containing Au. Of the one or more lower first metal layers 34B, the thickness of the metal layer containing Ni is equal to or greater than 1 μm and equal to or less than 5 μm. The thickness of the one or more lower first metal layers 34B is equal to or greater than 1.01 μm and equal to or less than 5.1 μm.

The lower metal layers 33B include a lower second metal layer 35B provided between the ceramic substrate 31 and one or more lower first metal layers 34B. The lower second metal layer 35B is a metal layer containing Cu. The main material of the lower second metal layer 35B is Cu. A metal other than Cu that has good heat dissipation properties may be used for the lower second metal layer 35B.

The thickness of the lower second metal layer 35B is greater than the thickness of the one or more lower first metal layers 34B. The thickness of the lower second metal layer 35B is equal to or greater than 10 μm and equal to or less than 100 μm. The lower second metal layer 35B is the thickest of the lower metal layers 33B.

The lower metal layers 33B do not include a metal layer 32 containing at least Pt provided on the lower surface side of the one or more lower first metal layers 34B on the lower surface side of the ceramic substrate 31. A metal layer 32 containing at least Pt is not provided on the lower surface side of the ceramic substrate 31.

The lower metal layers 33B include a bottom metal layer 37B provided at the lowest position among the multiple lower metal layers 33B. The bottom metal layer 37B is a metal layer containing Au, or a metal layer containing an AuSn alloy. The thickness of the bottom metal layer 37B is equal to or greater than 0.1 μm and equal to or less than 7 μm. The bottom metal layer 37B may constitute the lower surface of the submount 30.

In relation to the bottom metal layer 37B, the one or more lower first metal layers 34B can be considered to be intermediate metal layers provided between the ceramic substrate 31 and the bottom metal layer 37B. Similarly, in relation to the bottom metal layer 37B, the lower second metal layer 35B can be considered to be an intermediate metal layer provided between the ceramic substrate 31 and the bottom metal layer 37B.

The lower metal layers 33B include a top metal layer 38B that is at the highest position among the lower metal layers 33B. The top metal layer 38B may be a metal layer containing TiW, a metal layer containing Cu, or a metal layer containing Ni. The thickness of the top metal layer 38B is equal to or greater than 0.05 μm and equal to or less than 0.15 μm.

### Reflective Member 40

The reflective member 40 has a light reflective surface that reflects light. The light reflective surface is inclined with respect to a lower surface thereof. That is, the positional relationship of the light reflective surface as viewed from the lower surface is neither perpendicular nor parallel. A straight line connecting the lower end and the upper end of the light reflective surface is inclined with respect to the lower surface of the reflective member 40. The angle of the light reflective surface with respect to the lower surface, or the angle of a straight line connecting the lower end and the upper end of the light reflective surface with respect to the lower surface, will be referred to as the inclination angle of the light reflective surface.

In the reflective member 40 depicted in the drawings, the light reflective surface is flat and forms an inclination angle of 45 degrees with respect to the lower surface of the reflective member 40. The light reflective surface does not have to be flat, and may instead be a curved surface, for example. Also, the inclination angle of the light reflective surface need not be 45 degrees.

Glass or a metal can be used as the main material of the reflective member 40. The main material is preferably a material that is resistant to heat, such as quartz, or glass such as BK7 (borosilicate glass), or a metal such as aluminum. The reflective member 40 can also be formed using Si as the main material. In the case where the main material is a reflective material, the light reflective surface may be formed of the main material. In the case where the light reflective surface is formed of a material other than the main material, the light reflective surface can be formed using a metal such as Ag or Al, or a dielectric multilayer film such as Ta₂O₅/SiO₂, TiO₂/SiO₂, or Nb₂O₅/SiO₂.

The light reflective surface has a reflectance of 90% or more with respect to the peak wavelength of light irradiating the light reflective surface. This reflectance may be 95% or more. This reflectance may also be 99% or more. The light reflectance is equal to or less than 100%, or less than 100%.

### Protective Element 50

The protective element 50 is used to prevent excessive current from flowing through a certain element (such as the semiconductor laser element 20) and damaging that element. An example of the protective element 50 is a Zener diode. The Zener diode may be made of Si.

### Conducting Member 60

The conducting member 60 is a linear-shaped conductive material with bonding portions at both ends thereof. The bonding portions at both ends serve as portions to be bonded with other constituent elements. The conducting member 60 is a metal wire, for example. For instance, gold, aluminum, silver, copper, or the like can be used as the metal.

### Optical Member 80

The optical member 80 has an upper surface, a lower surface, and lateral surfaces. The optical member 80 has optical effects on the incident light, such as reflection, transmission, and refraction, and optical effects such as focusing, diffusing, and collimating.

The optical member 80 may have one or more lens surfaces. The one or more lens surfaces are provided on the upper surface side of the optical member 80, or may be provided on the lower surface side of the optical member 80. The upper surface and the lower surface are flat. The one or more lens surfaces intersect the upper surface. The one or more lens surfaces are surrounded by the upper surface in a top view. In top view, the optical member 80 has a rectangular outer shape. The lower surface of the optical member 80 is rectangular.

The portion of optical member 80 that overlaps one or more lens surfaces in a top view is referred to as a “lens portion”. The portion of the optical member 80 that overlaps the upper surface in a top view is referred to as a “non-lens portion”. The lens surface side when the lens portion is bisected by an imaginary plane including the upper surface is referred to as a “lens shaped portion,” and the lower surface side is referred to as a “flat plate shaped portion.” The lower surface of the lens portion is a part of the lower surface. In the optical member 80, the lower surface is made of the lower surface of the lens portion and the lower surface of the non-lens portion.

The optical member 80 depicted in the drawings has a plurality of lens surfaces. These lens surfaces are formed continuously in one direction. The optical member 80 has four lens surfaces, and is formed such that the vertices of these four lens surfaces align in a straight line.

As used herein, the direction in which the lens surfaces are arranged in a top view is referred to as the coupling direction. A length of the lens surfaces in the coupling direction in a top view is greater than a length of the lens surfaces in a direction perpendicular to the coupling direction. In the optical member 80 depicted in the drawings, the coupling direction is the same as the X direction.

The optical member 80 has high light transmittance. The optical member 80 has high light transmittance in both the lens portion and the non-lens portion. Also, the optical member 80 as a whole has high light transmittance. The optical member 80 can be formed using glass such as BK7, for example.

### Light-Emitting Device 1

The light-emitting device 1 having the above-mentioned constituent elements will now be described.

In the light-emitting device 1, one or more semiconductor laser elements 20 are disposed on the mounting surface 11D. The one or more semiconductor laser elements 20 are disposed so that their light-emitting surfaces face to a lateral side. The one or more semiconductor laser elements 20 are disposed so that their light-emitting surfaces face in the same direction. The “same direction” here includes a case in which the rotational deviation in a plane parallel to the mounting surface 11D between the light-emitting surfaces of adjacent semiconductor laser elements 20 is within a range of #5 degrees. In the light-emitting device 1 depicted in the drawings, the semiconductor laser elements 20 are aligned in the X direction.

In the light-emitting device 1, one or more submounts 30 are disposed on the mounting surface 11D. One or more semiconductor laser elements 20 are disposed on the upper surface of each of the one or more submounts 30. The one or more semiconductor laser elements 20 include a semiconductor laser element 20 disposed on the mounting surface 11D via the submount 30.

One or more semiconductor laser elements 20 can be disposed on a single submount 30. In the light-emitting device 1 depicted in the drawings, the number of semiconductor laser elements 20 disposed on a single submount 30 is one.

The one or more semiconductor laser elements 20 include a semiconductor laser element 20 that is disposed on the submount 30 and oscillates in TM mode. Accordingly, the light emitted from the semiconductor laser element 20 disposed on the submount 30 can have a good polarization ratio. This will be described in further detail.

FIG. 10B is a cross-sectional view showing the structure of the submount 99 used in an experiment that compares with the submount 30. The submount 99 differs from the submount 30 in that the upper metal layer does not include a metal layer containing Ni. That is, the submount 99 does not include a structure corresponding to the one or more upper first metal layers 34A in the submount 30. The submount 99 also differs from the submount 30 in that the lower metal layer include a metal layer containing Pt instead of including the metal layer containing Ni. In the submount 99, a metal layer of Ti/Pt/Au is employed as the one or more lower first metal layers, whereas a metal layer of Ni/Au is employed as the one or more lower first metal layers 34B in the submount 30. In FIG. 10B, those portions corresponding to those of the submount 30 are numbered the same as in the submount 30 in FIG. 10A.

Tables 1 to 4 show the results of the polarization ratio measurement experiments conducted using the submount 30 and the submount 99. FIG. 11 is a schematic diagram of the experiment conditions when the experimental data in Tables 1 to 4 was obtained. In a state in which the semiconductor laser element 20 was disposed on the submount 30 or the submount 99, the light emitted from the semiconductor laser element 20 was caused to pass through a collimator lens E1, collimated, and measured. Furthermore, in the measurement of the polarization ratio, a Glan-Laser Calcite Polarizer manufactured by Thorlabs was used as the polarizer E2, a metal film ND filter manufactured by Melles Griot was used as the ND filter E3, and a detector photodiode manufactured by Hamamatsu Photonics was used as the detector photodiode E4.

In the submount 30 used in the experiment, the ceramic substrate 31 is a ceramic substrate whose main material is AlN, both the one or more upper first metal layers 34A and the one or more lower first metal layers 34B are a Ni metal layer of 2.5 μm and an Au metal layer of 0.02 μm, each of the upper second metal layer 35A and the lower second metal layer 35B is a Cu metal layer, the one or more upper third metal layers 36A are formed of a Ti/Pt/Au metal layer of 0.56 μm and a Pt metal layer of 0.3 μm, the top metal layer 37A of the upper metal layer 33A is an Au metal layer of 0.05 μm disposed on a 2.5 μm AuSn metal layer, the bottom metal layer 37B of the lower metal layer 33B is a AuSn metal layer of 5 μm, and the bottom metal layer 38A of the upper metal layer 33A and the top metal layer 38B of the lower metal layer 33B are both a TiW metal layer of 0.1 μm.

Also, in the submount 99 used in the experiment, the ceramic substrate is a ceramic substrate whose main material is AlN, the one or more lower first metal layers 34B are a Ti metal layer of 0.06 μm, a Pt metal layer of 0.2 μm, and a Au metal layer of 0.3 μm, each of the upper second metal layer and the lower second metal layer is a Cu metal layer, the one or more upper third metal layers are formed of a Ti/Pt/Au metal layer of 0.56 μm and a Pt metal layer of 0.3 μm, the top metal layer of the upper metal layer is a Au metal layer of 0.05 μm provided on a AuSn metal layer of 2.5 μm, the bottom metal layer of the lower metal layer is a AuSn metal layer of 5 μm, and the bottom metal layer of the upper metal layer and the top metal layer of the lower metal layer are TiW metal layers of 0.1 μm.

Table 1 shows the results of measuring the polarization ratio (TE/TM) of a semiconductor laser element disposed on the submount 99 and a semiconductor laser element mounted on the submount 30, with the thicknesses of the ceramic substrate, the upper second metal layer, and the lower second metal layer, which form the main thickness of the submount, being uniform. Both semiconductor laser elements are semiconductor laser elements that oscillate in TM mode and are manufactured by the same manufacturing process.

TABLE 1

| | Submount 99 | Submount 30 |
|---|---|---|
| Thickness of ceramic substrate (μm) | 150 | 150 |
| Thickness of upper second metal | 75 | 75 |
| layer (Cu layer) (μm) | | |
| Thickness of lower second metal | 75 | 75 |
| layer (Cu layer) (μm) | | |
| Polarization Ratio | 74.5 | 169.9 |

Thus, it can be seen from the experiment results in Table 1 that when the submounts 99 and 30, having substantially the same thickness, are compared with each other, the submount 30 has a higher polarization ratio. This result leads to the assumption that the Ni metal layer 32 and the Au metal layer 32 in the upper first metal layer 34A of the submount 30 affect the difference in the polarization ratio value. Also, given that the upper metal layer of the submount 99 also includes a Au metal layer, it is assumed that the presence of the Ni metal layer 32 greatly affects the difference in the polarization ratio value.

Table 2 shows the results of measuring the polarization ratio of semiconductor laser elements disposed on the submount 30, with the ceramic substrate 31 having the same thickness and the upper second metal layer and the lower second metal layer having different thicknesses. All of the semiconductor laser elements are semiconductor laser elements that oscillate in TM mode and are manufactured by the same manufacturing process.

TABLE 2

| | Submount | Submount | Submount | Submount |
|---|---|---|---|---|
| | 30 | 30 | 30 | 30 |
| Thickness of | 150 | 150 | 150 | 150 |
| ceramic | | | | |
| substrate (μm) | | | | |
| Thickness of | 15 | 25 | 35 | 75 |
| upper second | | | | |
| metal layer | | | | |
| (Cu layer) (μm) | | | | |
| Thickness of | 15 | 25 | 35 | 75 |
| lower second | | | | |
| metal layer | | | | |
| (Cu layer) (μm) | | | | |
| Polarization | 178.6 | 184.3 | 168.3 | 177.4 |
| Ratio | | | | |

Thus, it can be seen from the experiment results in Table 2 that there was not a great difference in the polarization ratio value when the thicknesses of the upper second metal layer and the lower second metal layer in the submount were changed. From these results, it is assumed that the thicknesses of the upper second metal layer 35A and the lower second metal layer 35B of the submount 30 have very little effect on the difference in the polarization ratio value.

Table 3 shows the results of measuring the polarization ratio of semiconductor laser elements disposed on the submount 99, with the same thickness of the submount and different thicknesses of the ceramic substrate. All of the semiconductor laser elements are semiconductor laser elements that oscillate in TM mode and are manufactured by the same manufacturing process.

TABLE 3

| | Submount | Submount | Submount |
|---|---|---|---|
| | 99 | 99 | 99 |
| Thickness of | 150 | 200 | 250 |
| ceramic | | | |
| substrate (μm) | | | |
| Thickness of | 75 | 50 | 25 |
| upper second | | | |
| metal layer | | | |
| (Cu layer) (μm) | | | |
| Thickness of | 75 | 50 | 25 |
| lower second | | | |
| metal layer | | | |
| (Cu layer) (μm) | | | |
| Polarization | 54.5 | 58.0 | 74.6 |
| Ratio | | | |

Thus, the experiment results in Table 3 exhibited that there was not a great difference in the polarization ratio between the submount 99 having a ceramic substrate thickness of 150 μm and the submount 99 having a ceramic substrate thickness of 200 μm. On the other hand, it can be seen that the submount 99 in which a thickness of a ceramic substrate is 250 μm has a higher polarization ratio than both the submounts 99 having ceramic substrate thicknesses of 150 μm and 200 μm. From these results, it is assumed that the polarization ratio of the submount 30 can also be relatively increased by increasing a thickness the ceramic substrate 31 to some degree.

However, as can be seen from a comparison of Tables 1 and 3, the variation in the polarization ratio value depending on the thickness of the ceramic substrate is less than the variation in the polarization ratio value depending on the difference between submount 30 and submount 99 in the experiment in Table 1. In the submount 30, the ceramic substrate 31 greatly affects the thickness of the submount 30, and a change in the thickness of the ceramic substrate results in a change in the thickness of the submount 30, which can greatly affect the design of the mounting positions and other aspects of the other constituent elements of the light-emitting device 1. Accordingly, these influences needs to be taken into account for determining the thickness of the ceramic substrate 31.

Table 4 shows the results of measuring the polarization ratio value in the case where a semiconductor laser element oscillating in TM mode and a semiconductor laser element oscillating in TE mode are disposed on the submounts 30 that are equivalent to each other, and the results of measuring the polarization ratio value in the case where a semiconductor laser element oscillating in TM mode and a semiconductor laser element oscillating in TE mode are disposed on the submounts 99 that are equivalent to each other. Both of the semiconductor laser elements oscillating in TM mode are semiconductor laser elements manufactured by the same manufacturing process, and both of the semiconductor laser elements oscillating in TE mode are semiconductor laser elements manufactured by the same manufacturing process. Also, both the semiconductor laser element oscillating in TM mode and the semiconductor laser element oscillating in TE mode are semiconductor laser elements that emit red light. More specifically, the emission peak wavelength of the semiconductor laser element oscillating in TM mode is in the range of 638 to 642 nm, and the emission peak wavelength of the semiconductor laser element oscillating in TE mode is in the range of 638 to 642 nm. Also, the semiconductor laser element that oscillates in TM mode has two emitters, and the semiconductor laser element that oscillates in TE mode has one emitter.

TABLE 4

| | TE mode | TE mode | TM mode | TM mode |
|---|---|---|---|---|
| | LD | LD | LD | LD |
| | Submount | Submount | Submount | Submount |
| | 99 | 30 | 99 | 30 |
| Thickness of | 250 | 150 | 250 | 150 |
| ceramic | | | | |
| substrate (μm) | | | | |
| Thickness of | 25 | 25 | 25 | 25 |
| upper second | | | | |
| metal layer | | | | |
| (Cu layer) (μm) | | | | |
| Thickness of | 25 | 25 | 25 | 25 |
| lower second | | | | |
| metal layer | | | | |
| (Cu layer) (μm) | | | | |
| Polarization | 68.5 | 66.7 | 74.6 | 184.3 |
| Ratio | | | | |

Thus, it can be seen from the experiment results in Table 4 that, with a semiconductor laser element oscillating in TE mode, no significant change in the polarization ratio value was observed even when the submount 99 was replaced with the submount 30, whereas, with a semiconductor laser element oscillating in TM mode, an improvement in the polarization ratio value was observed when using the submount 30 in place of the submount 99.

As shown in the experiment, using the submount 30 in place of the submount 99 resulted in a relatively good polarization ratio of light emitted from TM mode semiconductor laser element, and this may be influenced by a difference in the tensile strain between the submount 99 and the submount 30 due to the presence of the metal layer containing Ni.

The submount 99 and the submount 30 used in the experiments bad a rectangular shape in a top view, with a long side of 1.6 mm and a short side of 1.2 mm. The semiconductor laser elements 20 oscillating in TM mode disposed on these submounts had a rectangular shape in a top view, with a long side of 1.5 mm and a short side of 0.4 mm. The warpage amounts in the long side direction and the short side direction of the semiconductor laser elements 20 disposed on the submount 99 and the submount 30 were measured, which revealed that the warpage amount in the long side direction of the semiconductor laser element 20 disposed on the submount 30 was larger than that of the semiconductor laser element 20 disposed on the submount 99. More specifically, warpage in the range of 0.4 to 0.9 μm in the long side direction was observed with the submount 30, and warpage in the range of 0.2 to 0.6 μm in the long side direction was observed with the submount 99. Also, the warpage in the short side direction of the semiconductor laser element 20 disposed on the submount 30 was smaller than that of the semiconductor laser element 20 disposed on the submount 99. More specifically, warpage in the range of 0.01 to 0.03 μm in the short side direction was observed in that with the submount 30, while warpage in the range of 0.03 to 0.05 μm in the short side direction was observed in that with the submount 99.

The description of the light-emitting device 1 will now continue.

In the light-emitting device 1, the polarization ratio of light emitted from the one or more semiconductor laser elements 20 disposed on the submount 30 and oscillating in TM mode is 100 or more. For example, in the case where this light is used for image display, a polarization ratio of 100 or more may be needed, and a light-emitting device 1 that emits light with a good polarization ratio can be realized. The value of this polarization ratio may be based on the result of measurement of the light emitted from the semiconductor laser element 20.

In the light-emitting device 1, the polarization ratio of light emitted from the one or more semiconductor laser elements 20 disposed on the submount 30 and oscillating in TM mode is 150 or more. The value of this polarization ratio may be based on the result of measuring the light emitted from the semiconductor laser element 20.

The one or more semiconductor laser elements 20 may include one or more semiconductor laser elements 20 that oscillate in TM mode and one or more semiconductor laser elements 20 that oscillate in TE mode.

As used herein, a semiconductor laser element 20 included in the one or more semiconductor laser elements 20 and oscillating in TM mode will be referred to as a first semiconductor laser element 20A, and a semiconductor laser element 20 included in the one or more semiconductor laser elements 20 and oscillating in TE mode will be referred to as a second semiconductor laser element 20B.

Each of the one or more first semiconductor laser elements 20A is disposed on the submount 30. The one or more second semiconductor laser elements 20B may be disposed on submount(s) other than the submount 30. For instance, the one or more second semiconductor laser elements 20B may include a semiconductor laser element 20 disposed on the above-mentioned submount 99. Also, the one or more second semiconductor laser elements 20B may include a semiconductor laser element 20 disposed on the submount 30.

Advantage in terms of polarization ratio obtained by disposing the second semiconductor laser element 20B on the submount 30 is smaller than that obtained by disposing the first semiconductor laser element 20A on the submount 30, and accordingly the second semiconductor laser element 20B may be disposed on a submount other than the submount 30 for the sake of characteristics other than the polarization ratio (such as heat dissipation).

As used herein, the submount on which the first semiconductor laser element 20A is disposed shall be referred to as a first submount 30A, and the submount on which the second semiconductor laser element 20B is disposed will be referred to as a second submount 30B.

In the light-emitting device 1, the first submount 30A and the second submount 30B are disposed on the mounting surface 11D. In the light-emitting device 1, the second submount 30B can be a submount that does not contain at least some of the materials contained in the submount 30, or that contains a material different from the materials contained in the submount 30.

The submount 30 is employed in at least one of the one or more first submounts 30A. The submount 99 can be employed in at least one of the one or more second submounts 30B. The submount 30 may also be employed in at least one of the one or more second submounts 30B.

In the light-emitting device 1, the one or more first semiconductor laser elements 20A include a semiconductor laser element 20 that emits red light. This semiconductor laser element 20 can be a semiconductor laser element including an active layer made of a GaAs-based material.

In the light-emitting device 1, the one or more second semiconductor laser elements 20B include a semiconductor laser element 20 that emits light of a color different from that of the light emitted from the one or more first semiconductor laser elements 20A. At least one second semiconductor laser element 20B emits light of a color different from that of the light emitted from the first semiconductor laser element 20A.

In the light-emitting device 1, the one or more second semiconductor laser elements 20B include a semiconductor laser element 20 that emits blue or green light. This semiconductor laser element 20 can be a semiconductor laser element that includes an active layer made of a GaN-based material.

The polarization ratio (TE/TM) of the light emitted from the first semiconductor laser element 20A is smaller than the polarization ratio (TM/TE) of the light emitted from the second semiconductor laser element 20B.

In the light-emitting device 1, the value of the polarization ratio (TM/TE) of the light emitted from the second semiconductor laser element 20B disposed on the second submount 30B, which is the submount 99, is larger than the polarization ratio (TE/TM) of the light emitted from the first semiconductor laser element 20A disposed on the first submount 30A, which is the submount 30. Thus, as the second semiconductor laser element 20B already has a sufficiently high polarization ratio, disposing the first semiconductor laser element 20A on the submount 30 allows for improving the polarization ratio of the light emitted from each of the one or more semiconductor laser elements 20 in the light-emitting device 1.

In the light-emitting device 1, the second submount 30B may have a metal layer that is made of the same material as the upper second metal layer 35A of the first submount 30A and is thicker than the upper second metal layer 35A. This makes it possible to form the second submount 30B with better heat dissipation properties than the first submount 30A, and to employ this for the second semiconductor laser element 20B.

In the light-emitting device 1, the second submount 30B may include a ceramic substrate, a metal layer made of the same material as the upper second metal layer 35A of the first submount 30A and thicker than the upper second metal layer 35A on the upper side of the ceramic substrate, and a metal layer made of the same material as the lower second metal layer 35B of the first submount 30A and thicker than the lower second metal layer 35B on the lower side of the ceramic substrate. This makes it possible to form the second submount 30B with better heat dissipation properties than the first submount 30A, and to employ this for the second semiconductor laser element 20B.

In the light-emitting device 1, the one or more semiconductor laser elements 20 include a first semiconductor laser element 20A that emits red light, a second semiconductor laser element 20B that emits green light, and a second semiconductor laser element 20B that emits blue light. The polarization ratio of the red light emitted from the light-emitting device 1 is 100 or more, the polarization ratio of the green light emitted from the light-emitting device 1 is 200 or more, and the polarization ratio of the blue light emitted from the light-emitting device 1 is 200 or more. A light-emitting device 1 that emits RGB light with a good polarization ratio can thus be realized.

In the light-emitting device 1, the one or more first semiconductor laser elements 20A include a semiconductor laser element 20 having a plurality of emitters. This semiconductor laser element 20 can emit red light.

In the light-emitting device 1, the one or more first semiconductor laser elements 20A include a semiconductor laser element 20 that is junction-down mounted on the first submount 30A. This semiconductor laser element 20 can emit red light. Furthermore, this semiconductor laser element 20 can have a plurality of emitters. Provided that tensile strain produced by the submount 30 affects the polarization ratio, when performing junction-down mounting, the area of contact with the submount 30 may be larger in the case of having a plurality of emitters. Therefore, there is a possibility that the influence on the polarization ratio caused by the submount 30 will be different between a first semiconductor laser element 20A having one emitter and a first semiconductor laser element 20A having a plurality of emitters.

In the light-emitting device 1, one or more reflective members 40 are disposed in the internal space of the package 10. The one or more reflective members 40 are disposed on the mounting surface 11D. The one or more reflective members 40 have one or more light reflective surfaces. Light emitted from the one or more semiconductor laser elements 20 is reflected by the one or more light reflective surfaces. The light reflective surfaces are inclined at an angle of 45 degrees to the traveling direction of the light passing through the optical axis. The light reflected by the light reflective surfaces travels upward. The one or more light reflective surfaces are irradiated with the main portions of a plurality of light beams.

The reflective member(s) 40 can be provided in a one-to-one relationship with respect to the semiconductor laser elements 20. In other words, the number of the reflective members 40 is the same as the number of semiconductor laser elements 20. All of the reflective members 40 have the same size and shape. The main portion of light from one semiconductor laser element 20 irradiates the light reflective surface of one reflective member 40. The light reflective surface of one reflective member 40 may be irradiated with the main portion of light from a plurality of semiconductor laser elements 20.

The light reflective surfaces of the reflective members 40 reflect 90% or more of the main portion of the irradiating light. In one example, the light-emitting device 1 does not include the reflective member 40. In this case, the light-emitting surface of the semiconductor laser element 20 faces upward, for example.

The light-emitting device 1 can include a plurality of reflective members 40. The plurality of reflective members 40 are disposed to be aligned in the same direction as the plurality of semiconductor laser elements 20 in top view. The optical axes of the plurality of light beams reflected by the one or more light reflective surfaces are parallel to each other.

In the light-emitting device 1, one or more protective elements 50 are disposed on a base member. The one or more protective elements 50 are disposed on a wiring pattern. The one or more protective elements 50 may be disposed at a position other than the wiring pattern. For example, they may be disposed on the submount 30. The one or more protective elements 50 are electrically connected to the wiring pattern. The protective element(s) 50 are provided in a one-to-one relationship with respect to the electrical circuit that electrically connects the one or more semiconductor laser elements 20.

In the light-emitting device 1, conducting members 60 are bonded to the wiring pattern. The light-emitting device 1 includes a plurality of conducting members 60. The plurality of conducting members 60 electrically connect the one or more semiconductor laser elements 20 to the base member.

The one or more conducting members 60 are bonded to the stepped portions 12C. The conducting member 60 electrically connecting a first semiconductor laser element 20A to the base member and the conducting member 60 electrically connecting a second semiconductor laser element 20B to the base member are bonded to different stepped portions 12C.

In the light-emitting device 1, a cover is disposed on the upper surface of the base member. Also, bonding the cover to the base member creates a closed space that is surrounded by the base member and the cover. This space is the internal space of the package 10, and is a space in which the one or more semiconductor laser elements 20 are disposed.

Bonding the cover to the base member under a specific atmosphere creates a hermetically sealed closed space. Hermetically sealing the space in which the semiconductor laser elements 20 are disposed allows for inhibiting deterioration of quality due to dust collection effect. The cover is transmissive to the light emitted from the semiconductor laser elements 20. At least 90% of the main portion of the light emitted from the semiconductor laser elements 20 passes through the cover and is emitted to the outside.

In the light-emitting device 1, the light from the first semiconductor laser elements 20A emitted from the package 10 has a polarization ratio of 100 or more. This polarization ratio may be a value obtained on the basis of the results obtained by measuring the light emitted from the semiconductor laser elements 20 and the package 10.

The optical member 80 is disposed above the cover. The optical member 80 is bonded to the cover. The plurality of light beams emitted from the cover are incident on the incident surface of the optical member 80. The light beams incident on the incident surface of the optical member 80 are emitted from the lens surface.

The optical member 80 is disposed such that each of the one or more lens surfaces overlap with a respective one of the mutually different semiconductor laser elements 20 in a top view. The main portion of light emitted from each of the mutually different semiconductor laser elements 20 is emitted from a respective one of the one or more lens surfaces. A single lens surface corresponds to a single semiconductor laser element 20, and light from each semiconductor laser element 20 is emitted from a corresponding lens surface.

In the light-emitting device 1, the light from the first semiconductor laser elements 20A emitted from the optical member 80 has a polarization ratio of 100 or more. This polarization ratio may be a value obtained on the basis of the results obtained by measuring the light emitted from the semiconductor laser elements 20 and the optical member 80. This light may pass through the package 10 before being incident on the optical member 80.

In the light-emitting device 1, the light from the first semiconductor laser elements 20A emitted from the light-emitting device 1 has a polarization ratio of 100 or more. The polarization ratio may be a value obtained on the basis of measuring either the light emitted from the semiconductor laser elements 20, the light emitted from the package 10, or the light emitted from the optical member 80. For example, in the case where the light-emitting device 1 does not include a covering portion 17, this ratio may be a value obtained on the basis of measuring either the light emitted from the semiconductor laser elements 20 or the light emitted from the optical member 80.

Although embodiments according to the present invention has been described above, the light-emitting device according to the present invention is not strictly limited to the light-emitting device in the embodiments. In other words, the present invention can be achieved without being limited to an outer shape or a structure of the light-emitting device disclosed by the embodiments. The present invention may be applied without requiring all the components being sufficiently provided. For example, in a case in which some of the components of the light-emitting device disclosed by the embodiments are not stated in the claims, the degree of freedom in design by those skilled in the art such as substitutions, omissions, shape modifications, and material changes for those components is allowed, and then the invention stated in the claims being applied to those components is specified.

Throughout the contents described in this description, the following aspects are disclosed.

### (Aspect 1)

A light-emitting device, comprising:
a first submount comprising
   a ceramic substrate containing AlN, and
   a plurality of upper metal layers disposed on an upper surface side of the ceramic substrate; and
a first semiconductor laser element disposed on an upper surface of the first submount, and configured to oscillate in a TM mode,
wherein the plurality of upper metal layers include one or more upper first metal layers comprising a metal layer containing at least Ni.

### (Aspect 2)

The light-emitting device according to aspect 1, wherein the plurality of upper metal layers include a top metal layer that is provided at the uppermost position among the plurality of upper metal layers, and
the one or more upper first metal layers are intermediate metal layers disposed between the ceramic substrate and the top metal layer.

### (Aspect 3)

The light-emitting device according to aspect 2, wherein the top metal layer is a metal layer containing Au or a metal layer containing an AuSn alloy.

### (Aspect 4)

The light-emitting device according to any one of aspects 1 to 3, wherein the plurality of upper metal layers include an upper second metal layer disposed on the upper surface side of the ceramic substrate, the upper second metal layer located between the ceramic substrate and the one or more upper first metal layers, and
a thickness of the upper second metal layer is greater than a thickness of the one or more upper first metal layers.

### (Aspect 5)

The light-emitting device according to any one of aspects 1 to 4, wherein the plurality of upper metal layers include one or more upper third metal layers on the upper surface side of the ceramic substrate, the one or more upper third metal layers including a metal layer that contains at least Pt on the upper surface side of the one or more upper first metal layers.

### (Aspect 6)

The light-emitting device according to any one of aspects 1 to 5, wherein
the first submount comprises
   one or more lower first metal layers that include a metal layer containing at least Ni and located on the lower surface side of the ceramic substrate, and
   a lower second metal layer disposed on the lower surface side of the ceramic substrate, the lower second metal layer located between the ceramic substrate and the one or more lower first metal layers, and
no metal layer containing at least Pt is provided on the lower surface side of the ceramic substrate.

### (Aspect 7)

The light-emitting device according to any one of aspects 1 to 6, further comprising a mounting member that has a mounting surface on which the first submount is disposed,
wherein a main material of the mounting member is a metal or ceramic.

### (Aspect 8)

The light-emitting device according to any one of aspects 1 to 7, wherein the first semiconductor laser element is configured to emit red light.

### (Aspect 9)

The light-emitting device according to any one of aspects 1 to 8, wherein the first semiconductor laser element has a plurality of emitters.

### (Aspect 10)

The light-emitting device according to any one of aspects 1 to 9, wherein the first semiconductor laser element is junction-down mounted on the first submount.

### (Aspect 11)

The light-emitting device according to any one of aspects 1 to 10, wherein a polarization ratio of the light from the first semiconductor laser element emitted from the light-emitting device is 100 or more.

### (Aspect 12)

The light-emitting device according to aspect 7, further comprising:
a second semiconductor laser element that oscillates in TE mode; and
a second submount on which the second semiconductor laser element is disposed, wherein the second submount is disposed on the mounting surface.

### (Aspect 13)

The light-emitting device according to aspect 12, wherein the second semiconductor laser element is configured to emit light of a color different from that of the light emitted from the first semiconductor laser element.

### (Aspect 14)

The light-emitting device according to aspect 12 or 13, wherein the second submount either does not contain at least some of all of the materials contained in the first submount, or contains a material that is different from all of the materials contained in the first submount.

### (Aspect 15)

A light-emitting device, comprising:
a first submount comprising
   a ceramic substrate containing AlN, and
   a plurality of lower metal layers disposed on a lower surface side of the ceramic substrate; and
a first semiconductor laser element disposed on the upper surface of the first submount and configured to oscillate in a TM mode,
wherein the plurality of lower metal layers include one or more lower first metal layers including a metal layer containing at least Ni.

### (Aspect 16)

The light-emitting device according to aspect 15, wherein the plurality of lower metal layers include a bottom metal layer that is disposed at a lowermost position among the plurality of lower metal layers, and
the one or more lower first metal layers are intermediate metal layers located between the ceramic substrate and the bottom metal layer.

### (Aspect 17)

The light-emitting device according to aspect 16, wherein the bottom metal layer is a metal layer containing an AuSn alloy.

### (Aspect 18)

The light-emitting device according to any one of aspects 15 to 17, wherein
the plurality of lower metal layers include a lower second metal layer disposed on the lower surface side of the ceramic substrate, the lower second metal layer located between the ceramic substrate and the one or more lower first metal layers, and
a thickness of the lower second metal layer is greater than a thickness of the one or more lower first metal layers.

### (Aspect 19)

The light-emitting device according to any one of aspects 15 to 18, further comprising a mounting member having a mounting surface on which the first submount is disposed,
wherein a main material of the mounting member is a metal or ceramic.

### (Aspect 20)

The light-emitting device according to any one of aspects 15 to 19, wherein the first semiconductor laser element is configured to emit red light.

### INDUSTRIAL APPLICABILITY

The light-emitting device according to the embodiments can be used for a projector, an on-vehicle headlight, a head-mounted display, lighting, a display, and the like.

### REFERENCE NUMERALS

1 Light-emitting device
   10 Package
      11A Top surface
      11B Bottom surface
      11D Mounting surface
      12C Step portion
      14 Base portion
      15 Frame portion
      17 Covering portion
   20 Semiconductor laser element
      20A First semiconductor laser element
      20B Second semiconductor laser element
   30 Submount
      31 Ceramic substrate
      32 Metal layer
         33A Upper metal layer
         34A Upper first metal layer
         35A Upper second metal layer
         36A Upper third metal layer
         37A Top metal layer
         38A Bottom metal layer
         33B Lower metal layer
         34B Lower first metal layer
         35B Lower second metal layer
         37B Bottom metal layer
         38B Top metal layer
      30A First submount
      30B Second submount
   40 Reflective member
   50 Protective element
   60 Conducting member
   80 Optical member
   99 Submount

1. A light-emitting device, comprising:
a first submount comprising
a ceramic substrate containing AlN, and
a plurality of upper metal layers disposed on an upper surface side of the ceramic substrate; and
a first semiconductor laser element disposed on an upper surface of the first submount, and configured to oscillate in a TM mode,
wherein the plurality of upper metal layers include one or more upper first metal layers comprising a metal layer containing at least Ni.

2. The light-emitting device according to claim 1, wherein the plurality of upper metal layers include a top metal layer that is provided at the uppermost position among the plurality of upper metal layers, and
the one or more upper first metal layers are intermediate metal layers disposed between the ceramic substrate and the top metal layer.

3. The light-emitting device according to claim 2, wherein the top metal layer is a metal layer containing Au or a metal layer containing an AuSn alloy.

4. The light-emitting device according to claim 1, wherein the plurality of upper metal layers include an upper second metal layer disposed on the upper surface side of the ceramic substrate, the upper second metal layer located between the ceramic substrate and the one or more upper first metal layers, and
a thickness of the upper second metal layer is greater than a thickness of the one or more upper first metal layers.

5. The light-emitting device according to claim 1, wherein the plurality of upper metal layers include one or more upper third metal layers on the upper surface side of the ceramic substrate, the one or more upper third metal layers including a metal layer that contains at least Pt on the upper surface side of the one or more upper first metal layers.

6. The light-emitting device according to claim 1, wherein
the first submount comprises
one or more lower first metal layers that include a metal layer containing at least Ni and located on the lower surface side of the ceramic substrate, and
a lower second metal layer disposed on the lower surface side of the ceramic substrate, the lower second metal layer located between the ceramic substrate and the one or more lower first metal layers, and
no metal layer containing at least Pt is provided on the lower surface side of the ceramic substrate.

7. The light-emitting device according to claim 1, further comprising a mounting member that has a mounting surface on which the first submount is disposed,
wherein a main material of the mounting member is a metal or ceramic.

8. The light-emitting device according to claim 1, wherein the first semiconductor laser element is configured to emit red light.

9. The light-emitting device according to claim 1, wherein the first semiconductor laser element has a plurality of emitters.

10. The light-emitting device according to claim 1, wherein the first semiconductor laser element is junction-down mounted on the first submount.

11. The light-emitting device according to claim 1, wherein a polarization ratio of the light from the first semiconductor laser element emitted from the light-emitting device is 100 or more.

12. The light-emitting device according to claim 7, further comprising:
a second semiconductor laser element that oscillates in TE mode; and
a second submount on which the second semiconductor laser element is disposed,
wherein the second submount is disposed on the mounting surface.

13. The light-emitting device according to claim 12, wherein the second semiconductor laser element is configured to emit light of a color different from that of the light emitted from the first semiconductor laser element.

14. The light-emitting device according to claim 12, wherein the second submount either does not contain at least some of all of the materials contained in the first submount, or contains a material that is different from all of the materials contained in the first submount.

15. A light-emitting device, comprising:
a first submount comprising
a ceramic substrate containing AlN, and
a plurality of lower metal layers disposed on a lower surface side of the ceramic substrate; and
a first semiconductor laser element disposed on the upper surface of the first submount and configured to oscillate in a TM mode,
wherein the plurality of lower metal layers include one or more lower first metal layers including a metal layer containing at least Ni.

16. The light-emitting device according to claim 15, wherein the plurality of lower metal layers include a bottom metal layer that is disposed at a lowermost position among the plurality of lower metal layers, and
the one or more lower first metal layers are intermediate metal layers located between the ceramic substrate and the bottom metal layer.

17. The light-emitting device according to claim 16, wherein the bottom metal layer is a metal layer containing an AuSn alloy.

18. The light-emitting device according to claim 15, wherein
the plurality of lower metal layers include a lower second metal layer disposed on the lower surface side of the ceramic substrate, the lower second metal layer located between the ceramic substrate and the one or more lower first metal layers, and
a thickness of the lower second metal layer is greater than a thickness of the one or more lower first metal layers.

19. The light-emitting device according to claim 15, further comprising a mounting member having a mounting surface on which the first submount is disposed,
wherein a main material of the mounting member is a metal or ceramic.

20. The light-emitting device according to claim 15, wherein the first semiconductor laser element is configured to emit red light.
